(19) United States
(12) Patent Application Publication
(10) Pub. No.: US 2007/0155304 A1
(43) Pub. Date: Jul. 5, 2007

(54) Air Conditioner

(75) Inventors: Seung-Yeup Hyun, Seoul (KR); Chan-Ho Song, (US); Jae-Hoon Sim, Seoul (KR)

Correspondence Address: KED & ASSOCIATES, LLP, P.O. Box 221200, Chantilly, VA, 20153-1200, US

(73) Assignee: LG Electronics Inc.

(21) Appl. No.: 11/646,333

(22) Filed: Dec. 28, 2006

(30) Foreign Application Priority Data
Dec. 29, 2005 (KR) 0134476/2005
Jan. 31, 2006 (KR) 0009446/2006

(51) Int. Cl. H01L 23/467; F24F 7/06; F25D 17/06

(52) U.S. Cl. 454/338; 62/426; 165/121

(57) ABSTRACT

An air conditioner comprising a casing having a receiving space therein and mounted in a ceiling, and an air supplying unit installed at a lower side of the casing for diffusing heat-exchanged air indoors, whereby the heat-exchanged air can evenly quickly be diffused indoors.

### RELATED APPLICATION

This application claims the benefit of Korean Application No. 10-2005-134476 and Korean Application No. 10-2006-9446, which were filed on Dec. 29, 2005, and Jan. 31, 2006, respectively, which are both hereby incorporated by reference in their entireties.

### BACKGROUND OF THE INVENTION

1. Field of the Invention

The present invention relates to an air conditioner, and particularly, to an air conditioner capable of evenly injecting heat-exchanged air indoors.

2. Background of the Invention

In general, air conditioners are placed in a space such as bedroom or living room or office to keep indoor air clean and comfortable by controlling temperature, humidity, cleanliness and air current.

The air conditioners may be divided into an integral air conditioner having refrigerating cycle components positioned inside a single casing, and a separate air conditioner having an indoor unit for heating or cooling indoor rooms and an outdoor unit for applying a compressed refrigerant to the indoor unit.

FIG. 1 is a sectional view showing an example of a related art air conditioner. As shown in FIG. 1, an air conditioner includes a casing 10 mounted in a ceiling in a room and having a receiving space therein, an indoor heat exchanger 21 received inside the casing 10 and having an annular shape, and a blowing fan 25 rotatably installed inside the indoor heat exchanger 21.

The casing 10 is formed in a rectangular shape and has an inlet 12 at a center portion of a lower surface for sucking indoor air. Each edge of the inlet 12 is provided with a plurality of outlets 14 for discharging air which has been sucked through the inlet 12 and heat-exchanged through the indoor heat exchanger.

However, the related art air conditioner has limitation in diffusion of the heat-exchanged air because the heat-exchanged air is discharged only in a certain direction due to the outlets 14 for discharging the heat-exchanged air being fixed. In order to solve the problem, a rotatable louver is mounted in each outlet 14 to change a wind direction, which, however, has limitation in evenly injecting air.

### SUMMARY OF THE INVENTION

Therefore, an object of the present invention is to provide an air conditioner capable of quickly diffusing heat-exchanged air indoors.

Another object of the present invention is to provide an air conditioner capable of distributing injection holes for injecting heat-exchanged air in a wider portion.

Another object of the present invention is to provide an air conditioner capable of quickly diffusing heat-exchanged air by applying the heat-exchanged air and forcibly circulating indoor air.

Another object of the present invention is to provide an air conditioner capable of forcibly circulating indoor air without changing temperature of the indoor air.

To achieve these and other advantages and in accordance with the purpose of the present invention, as embodied and broadly described herein, there is provided an air conditioner comprising: a casing having a receiving space therein and mounted in a ceiling; and an air supplying unit installed below the casing for diffusing heat-exchanged air into an indoor room.

In another embodiment of the present invention, there is provided an air conditioner comprising: a first refrigerant circulating unit including a compressor for compressing a first refrigerant, first and second heat exchangers connected to the compressor to allow circulation of the first refrigerant, and an expansion unit disposed between the first and second heat exchangers; and a second refrigerant circulating unit including a casing having a receiving space therein and mounted in a ceiling; an external air supplying unit movably installed below the casing, having therein a refrigerant passage for flowing a second refrigerant, and in which the second refrigerant is heat-exchangeable with indoor air, an intermediate heat exchanger formed to be heat-exchangeable with the first or second heat exchanger such that the second refrigerant is heat-exchanged with the first refrigerant, and connected to the external air supplying unit, and a circulation pump for circulating the second refrigerant to pass through the external air supplying unit and the intermediate heat exchanger.

In another embodiment of the present invention, there is provided an air conditioner comprising: a casing having a receiving space therein and mounted in a ceiling; an external air supplying unit having a refrigerant passage for flowing a refrigerant therein and rotatably installed below the casing; a heat exchanger installed inside the casing, connected to the external air supplying unit to allow the flow of the refrigerant, and adapted to heat or cool the refrigerant by means of a heating member or cooling member; and an indoor unit having a driving unit for rotating the external air supplying unit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sectional view showing an example of a related art air conditioner;

FIG. 2 is a sectional view showing an air conditioner in accordance with a first embodiment of the present invention;

FIG. 3 is a perspective view showing an external air supplying unit of FIG. 2;

FIG. 4 is an enlarged view showing a main portion of FIG. 2;

FIG. 5 is a sectional view taken along the line V-V of FIG. 3;

FIGS. 6 and 7 are perspective views showing variants of a rotating wing of the air conditioner of FIG. 2;

FIG. 8 is a view showing a variant of the external air supplying unit of the air conditioner of FIG. 2;

FIG. 9 is a perspective view showing the external air supplying unit of FIG. 8;

FIG. 10 is a sectional view showing an air conditioner in accordance with a second embodiment of the present invention;

FIG. 11 is a perspective view showing a rotating wing of FIG. 10;

FIG. 12 is a block diagram for the control of the air conditioner of FIG. 10;

FIG. 13 is a partial longitudinal sectional view showing an air conditioner in accordance with a third embodiment of the present invention;

FIG. 14 is a perspective view showing an external air supplying unit of FIG. 13;

FIG. 15 is an enlarged view showing a main portion of FIG. 13;

FIG. 16 is a plane sectional view showing a rotation shaft of FIG. 15;

FIG. 17 is an enlarged sectional view showing a wing portion of FIG. 14;

FIG. 18 is a plane sectional view of FIG. 17; and

FIG. 19 is a partial sectional view showing a variant of the wing portion of FIG. 13.

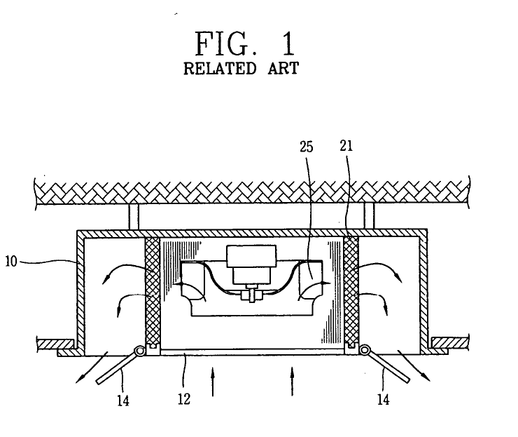

### DETAILED DESCRIPTION OF THE INVENTION

Description will now be given in detail of an outdoor unit of an air conditioner according to the present invention, and an operational method thereof with reference to the accompanying drawings.

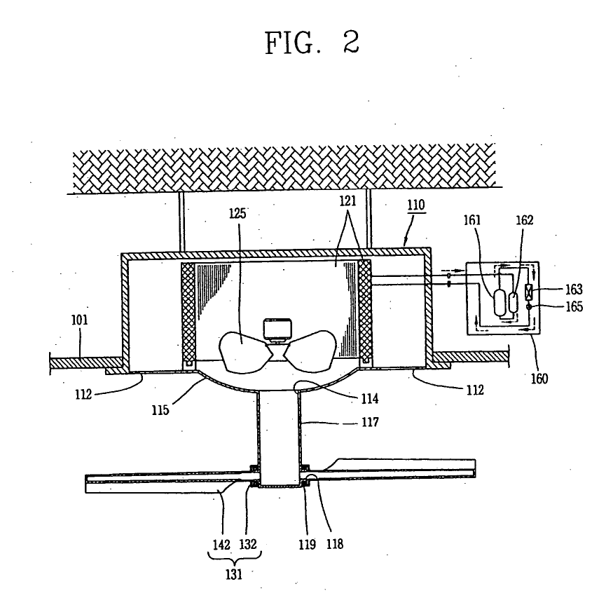

As shown in FIG. 2, an air conditioner according to the present invention includes a casing 110 having a receiving space therein and having an inlet 112 and an outlet 114 for sucking and discharging air, respectively, an indoor heat exchanger 121 disposed between the inlet 112 and the outlet 114 inside the casing 110, a blowing fan 125 installed in the casing 110, and an external air supplying unit 131 having an air passage therein wherein the air passage is communicated with the outlet 114.

The air conditioner is implemented in a ceiling type air conditioner which includes an indoor unit 100 mounted on the ceiling indoors and an outdoor unit 160 placed outside.

The outdoor unit 160 includes a compressor 161 for compressing a refrigerant, an outdoor heat exchanger 163 disposed such that the refrigerant is heat-exchangeable with outdoor air, and an expansion unit 165 for expanding the refrigerant with depressurization while passing therethrough. At one side of the compressor 161 is provided an accumulator 162 for sucking a gaseous refrigerant. Here, the outdoor unit 160 may be provided with a four-way valve (not shown) installed at a discharge side of the compressor 161 for switching a passage of the refrigerant, so as to allow a cooling and heating operation.

The casing 110 has an approximately rectangular shape to have a receiving space therein, and is typically mounted on an inner side of a ceiling 101 such that its lower portion is exposed to the indoor room. A plurality of inlets 112 are formed in each edge of a lower surface of the casing 110 for sucking air in, and a plurality of outlets 114 are formed in the center portion thereof to discharge inner air of the casing 110 to the outside.

The indoor heat exchanger 121 having an annular shape is installed inside the casing 110. The indoor heat exchanger 121 is connected to the outdoor unit 160. A blowing fan 125 is installed inside the indoor heat exchanger 121 so as to suck air through the inlets 112 and discharging it through the outlets 114. The blowing fan 125 may be implemented as a type of axial blower. A guide portion 115 having a circular arc shape for guiding air is formed at a lower center of the casing 110, and the outlets 114 for discharging air are formed at the center region of the guide portion 115.

A rotatable supporting unit 117 for rotatably supporting the external air supplying unit 131 is disposed at a lower end of the outlet 114. The rotatable supporting unit 117 has a tube shape such that air can flow therein. A plurality of discharging holes 118 for discharging air are formed at a lower end of the rotatable supporting unit 117 to be communicated in a radial direction of the rotatable supporting unit 117 and spaced apart from each other in a circumferential direction of the rotatable supporting unit 117. Bearings 119 are disposed at the circumference of the discharging holes 118 so as to rotatably support the external air supplying unit 131.

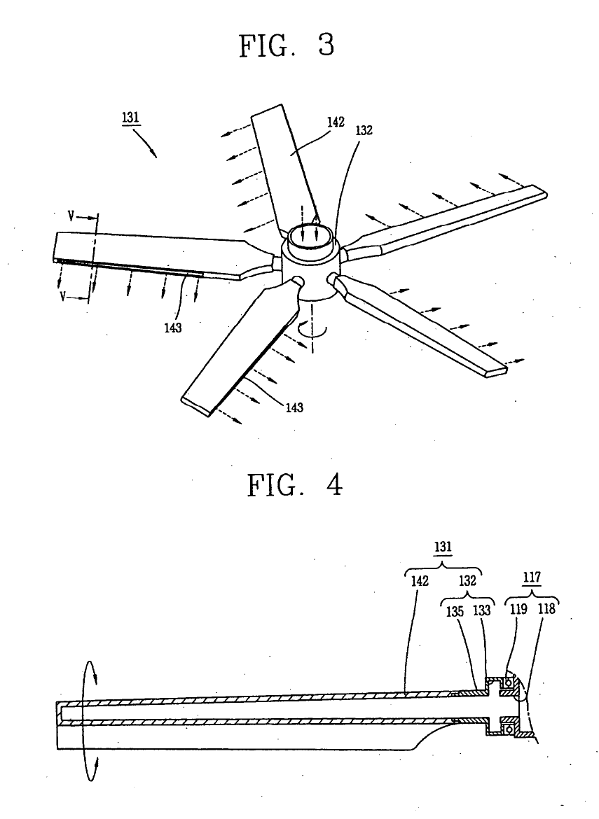

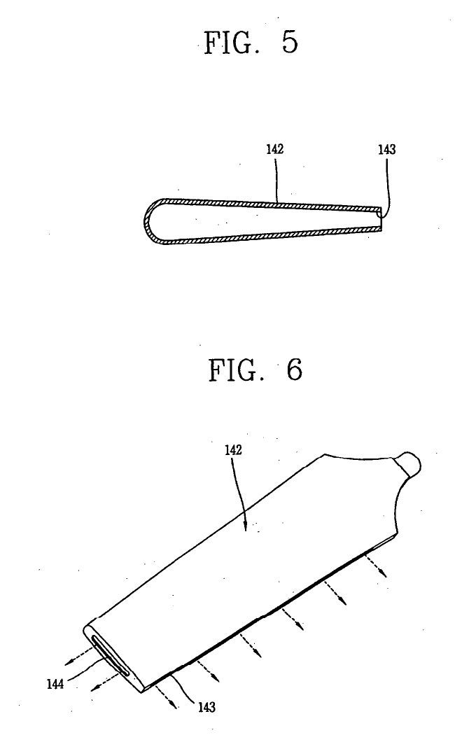

As shown in FIGS. 3 through 5, the external air supplying unit 131 includes a hub 132 rotatably coupled to the lower end of the rotatable supporting unit 117, and a plurality of rotating wings 142 outwardly extended from the hub 132 along a radial direction of the hub 132 and spaced apart from one another in a circumferential direction of the hub 132.

An inner space 133 is formed inside the hub 132 such that air discharged through each discharging hole 118 can flow therein. A plurality of coupling units 135 are formed at the circumference of the hub 132 to be outwardly protruded in a radial direction of the hub 132 and spaced apart from each other in a circumferential direction thereof. One end of each rotating wing 142 is rotatably coupled to each coupling unit 135 with being communicated with each other.

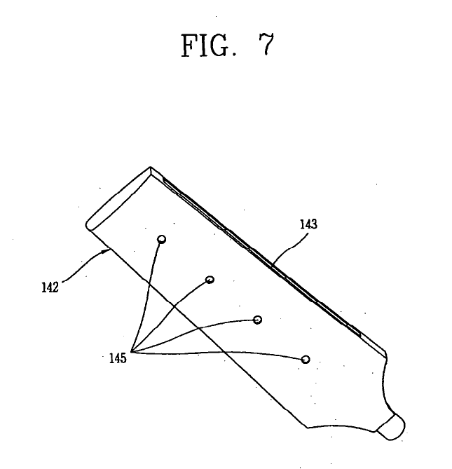

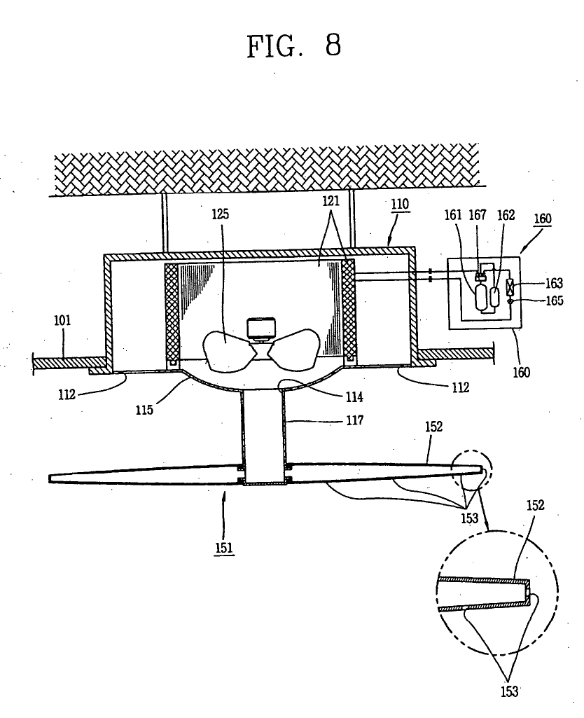

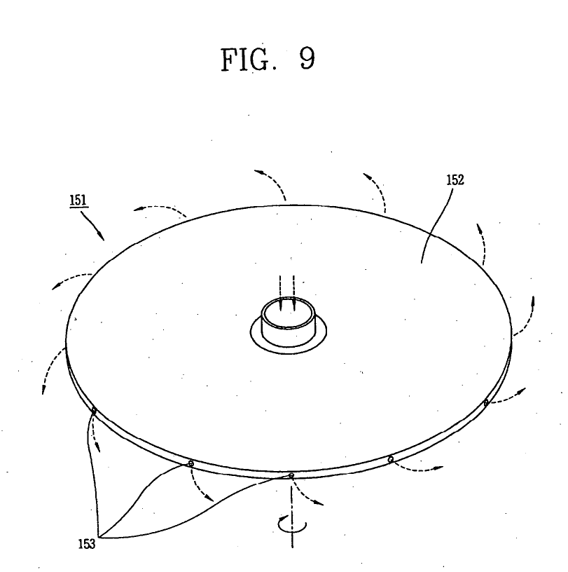

The rotating wing 142 has a long plate shape with a thin thickness and a narrow width, and has an air passage such that air can flow therein. An injection hole 143 having a slit shape is formed at a rear edge of the rotating wing 142 in a length direction so as to discharge inner air of the rotating wing 142. Here, in addition to the injection hole 143 formed at the rear edge of the rotating wing 142 for rotating the hub 132 and the rotating wings 142, a lateral injection hole 144, as shown in FIG. 6, may further be formed at an end portion of the length direction of at least one of the rotating wings 142 for diffusing heat-exchanged air, or a lower injection hole 145, as shown in FIG. 7, may further be formed at a lower surface of each rotating wing 142. Alternatively, both the lateral injection hole 144 and the lower injection hole 145 may be constructed at the same time. Furthermore, as shown in FIGS. 8 and 9, the external air supplying unit 151 may be formed in a discal shape and have a body 152 with plural injection holes 153 for injecting air at its circumferential surface and lower surface. In this respect, the external air supplying unit 151 can be implemented to be rotatable such that some or all of the injection holes 153 inject air to an opposite direction of a rotation direction.

In such construction, when the blowing fan 125 starts rotating, air flows into the casing 110 through the inlets 112 to be heat-exchanged through the indoor heat exchanger 121. The heat-exchanged air is discharged through the outlets 114. The discharged air flows downwardly along the rotatable supporting unit 117 and then is discharged into the inner space 133 of the hub 132 through the discharge holes 118. The air discharged into the inner space 133 of the hub 132 flows into each rotating wing 142 through each coupling unit 135 to thereafter be discharged through the injection hole 143 of each rotating wing 142. Accordingly, each rotating wing 142 discharges the heat-exchanged air through the corresponding injection hole 143 with rotating centering around the rotatable supporting unit 117.

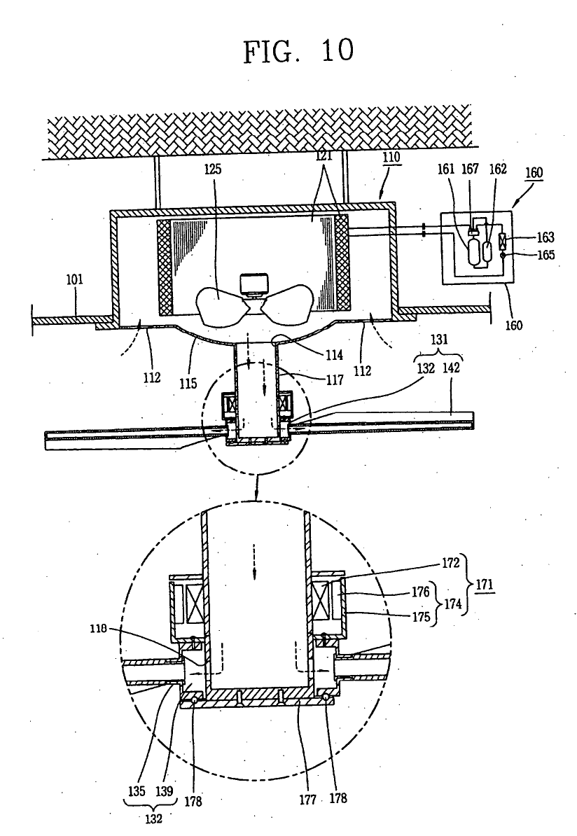

Hereinafter, an air conditioner in accordance with a second embodiment of the present invention will be explained with reference to the accompanying drawings. The same parts as the aforementioned configuration will be described by referring to the same reference numerals for the sake of explanation of drawings. As shown in FIG. 10, an air conditioner according to the present invention includes a casing 110 having a receiving space therein and having inlet 112 and outlet 114 for sucking and discharging air, respectively, an indoor heat exchanger 121 disposed between the inlet 112 and the outlet 114 inside the casing 110, a blowing fan 125 installed inside the casing 110, an external air supplying unit 131 having an air passage therein which is communicated with the outlet 114, and a driving unit implemented as a type of a driving motor 171 for rotating the external air supplying unit 131.

A plurality of inlets 112 for sucking air in are formed at a lower portion of the casing 110 along each edge, and a plurality of outlets 114 for discharging air are formed at the lower center portion of the casing 110.

The indoor heat exchanger 121 are disposed inside the casing 110 such that air which has been sucked through the inlets 112 and flows toward the outlets 114 can be heat-exchanged while passing therethrough. The indoor heat exchanger 121 is connected to the outdoor unit 160 for the flow of a refrigerant. The outdoor unit 160 includes a compressor 161 for compressing a refrigerant, an outdoor heat exchanger 163 disposed such that the refrigerant is heat-exchangeable with outdoor air, and an expansion unit 165 for expanding a refrigerant with depressurization. At one side of the compressor 161 is provided an accumulator 162 for sucking a gaseous refrigerant. Here, the outdoor unit 160 may be provided with a four-way valve (not shown) for switching a passage of the refrigerant so as to allow a cooling and heating operation.

In the meantime, a rotatable supporting unit 117 is downwardly extended from the outlet 114 so as to flow air therein and rotatably support the external air supplying unit 131. A plurality of air discharge holes 118 for discharging air are formed at a lower portion of the rotatable supporting unit 117.

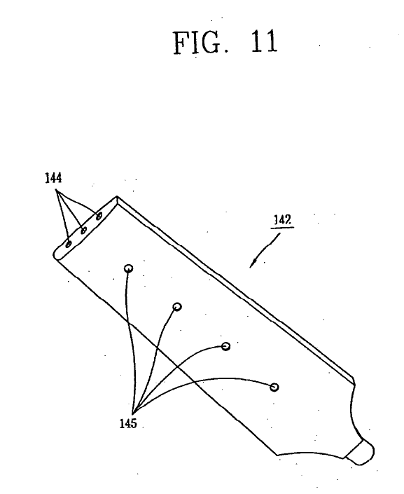

The external air supplying unit 131 includes a hub 132 having an air passage therein, and a plurality of rotating wings 142 each having one end outwardly extended from the hub 132. The hub 132 has a plurality of coupling units 135 to which the plurality of rotating wings 142 are coupled, respectively. A support plate 177 is installed at a lower side of the hub 132 to rotatably support the hub 132. Bearings 178 are interposed between the hub 132 and the support plate 177. Injection holes 144 and 145 for injecting air are formed respectively at an end surface and a lower surface of each rotating wing 142, as shown in FIG. 11. Here, the injection holes may be formed at a rear edge of each rotating wing 142 20 in a rotation direction of the hub 132.

A driving unit is formed at an upper side of the hub 132 to rotate the rotating wings 142. The driving unit may be implemented as a type of a driving motor 171 including a stator 172 fixed to the rotatable supporting unit 117 and a rotor 174 rotatably installed at an outer side of the stator 172. The rotor 174 includes a rotor frame 175 fixed to the hub 132, and a permanent magnet 176 disposed at an inner surface of the rotor frame 175 with being spaced apart from the stator 172 by an air gap.

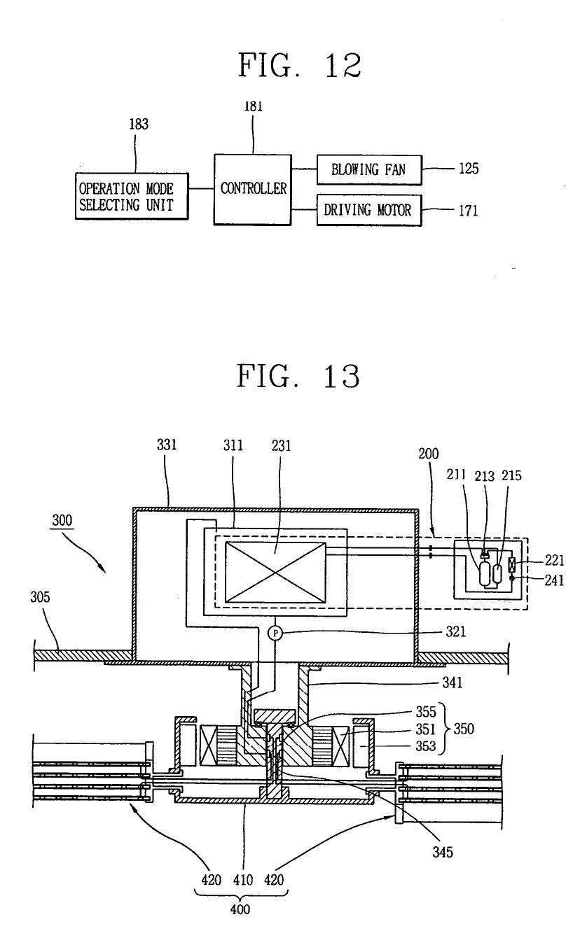

The air conditioner according to the present invention, as shown in FIG. 12, is provided with a controller 181 having a control program therein to thus control the blowing fan 125 and the driving motor 171 according to an operation mode. The controller 181 is connected respectively to an operation mode selecting unit 183 for selecting an operation mode, the blowing fan 125 and the driving motor 171. The operation modes may include a circulating mode for circulating indoor air by rotating the external air supplying unit 131 without working the refrigerating cycle, and a cooling or heating mode for rotating the external air supplying unit 131 while supplying heat-exchanged air indoors by working the refrigerating cycle.

In such configuration, when the cooling or heating mode is selected by the operation mode selecting unit 183, the controller 181 controls the blowing fan 125 and the external air supplying unit 131 to rotate. Upon the rotation of the blowing fan 125, air is sucked into the casing 110 through the inlets 112 and heat-exchanged through the indoor heat exchanger 121. The heat-exchanged air is discharged through the outlets 114. When the driving motor 171 starts rotating, the rotor 174 rotates, which results in the rotation of both the hub 132 and the rotating wings 142. Accordingly, the air discharged through the outlets 114 is discharged into the indoor room through the injection holes 144 and 145 of each rotating wing 142 via the hub 132.

When the circulating mode is selected, on the other hand, the controller 181 allows power to be applied to the driving motor 171. Each rotating wing 142 rotates accordingly, and the indoor air is forcibly circulated by the rotation of each of the rotating wings 142.

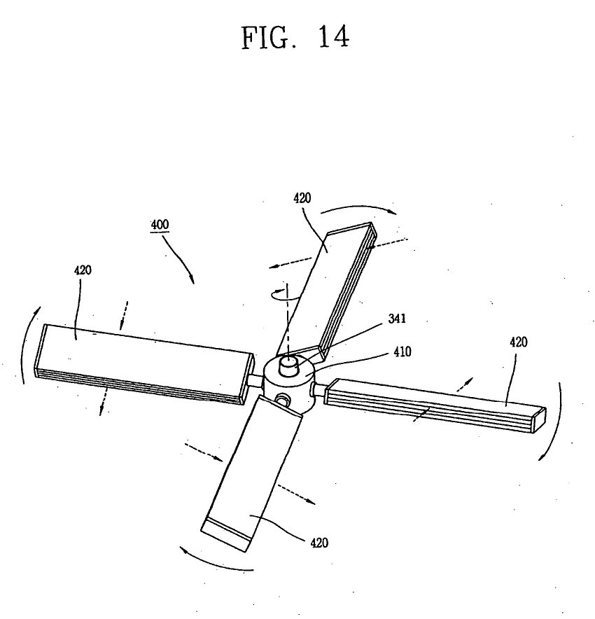

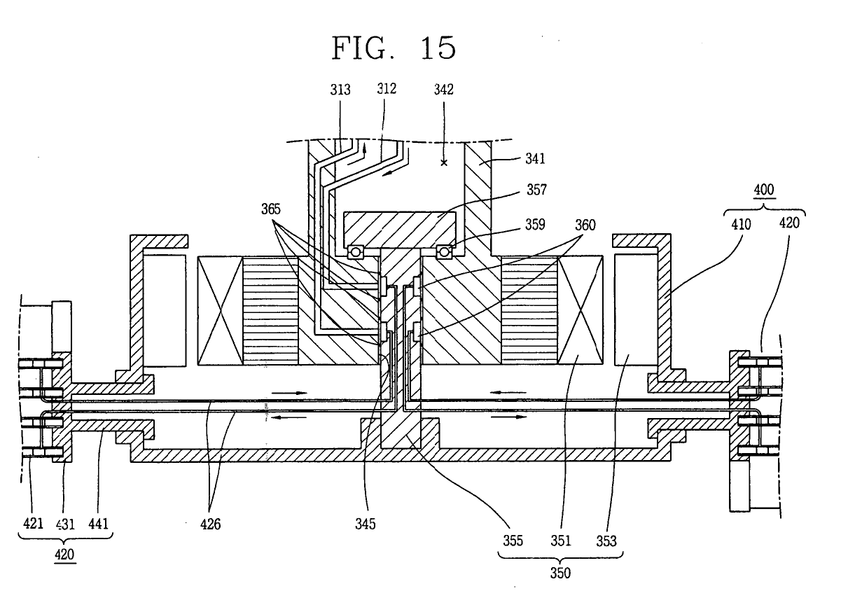

Hereinafter, an air conditioner according to a third embodiment of the present invention will be explained with reference to the drawings. As shown in FIGS. 13 to 15, an air conditioner according to the present invention includes a first refrigerant circulating unit 200 including a compressor 211 for compressing a first refrigerant, first heat exchanger 221 and second heat exchanger 231 each connected to the compressor 211 to allow the circulation of the first refrigerant, and an expansion unit 241 disposed between the first heat exchanger 221 and the second heat exchanger 231, and a second refrigerant circulating unit 300 including an intermediate heat exchanger 311 formed to be heat-exchangeable with the first heat exchanger 221 or the second heat exchanger 231 to thusly heat-exchange between a second refrigerant and the first refrigerant, an external air supplying unit 400 connected to the intermediate heat exchanger 311 such that the second refrigerant is heat-exchangeable with indoor air while rotating. The external air supplying unit 400 being rotatably installed indoors, and a circulation pump 321 disposed on a circulation path of the second refrigerant for circulating the second refrigerant.

The first refrigerant circulating unit 200 includes the compressor 211 for compressing the first refrigerant, the first heat exchanger 221 disposed at one side of the compressor 211 such that the first refrigerant is heat-exchangeable with outdoor air, the second heat exchanger 231 communicated with the compressor 211 and the first heat exchanger 221, respectively, and disposed to be heat-exchangeable with the second refrigerant, and the expansion unit 241 disposed between the first heat exchanger 221 and the second heat exchanger 231 for expanding the refrigerant with depressurization. An accumulator 215 is provided at a suction side of the compressor 211 for sucking a gaseous refrigerant. A four-way valve is installed at a discharge side of the compressor 211 for switching a passage of the refrigerant. Here, the first refrigerant may be a refrigerant which contains oil and is circulated by repeatedly performing processes such as compressing, condensing, expanding and evaporating. The first refrigerant circulating unit 200 may be implemented as a type of an outdoor unit including the compressor 211, the first heat exchanger 221 and the expansion unit 241, of components of the refrigerating cycle.

The second refrigerant circulating unit 300 includes the intermediate heat exchanger 311 formed to be heat-exchangeable between the first refrigerant and the second refrigerant, the external air supplying unit 400 connected to the intermediate heat exchanger 311 such that the second refrigerant is heat-exchangeable with indoor air and rotatably installed in an indoor room to be cooled or heat, and the circulation pump 321 for pumping the second refrigerant for its circulation. The second refrigerant may be an incompressible refrigerant such as brine. The second refrigerant circulating unit 300 may be implemented as a type of an indoor unit including a casing 331 and the second heat exchanger 231 of the first refrigerant circulating unit 200.

The casing 331 having a receiving space therein is mounted indoors in a ceiling 305. The intermediate heat exchanger 311 is received inside the casing 331 such that the second refrigerant is heat-exchangeable with the first refrigerant. The intermediate heat exchanger 311 may be formed in a cylindrical shape for receiving (containing) the second refrigerant therein. The second heat exchanger 231 for allowing the heat-exchange between the second refrigerant and the first refrigerant is installed inside the intermediate heat exchanger 311. The intermediate heat exchanger 311 is connected to an outlet tube 312 which the second refrigerant flows out and to an inlet tube 313 which the second refrigerant flows into. The circulation pump 321 is installed at the outlet tube 312 to pump the second refrigerant for its circulation.

A rotation supporting unit 341 is downwardly extended from a lower portion of the casing 331 so as to rotatably support the external air supplying unit 400. A driving unit 350 is formed at a lower portion of the rotation supporting unit 341 for driving the external air supplying unit 400 to rotate.

The driving unit 350 may be implemented as an outer rotor type driving motor which includes a stator 351 integrally fixed to the outside of a lower portion of the rotation supporting unit 341, a rotor 353 rotatably disposed at an outside of the stator 351 with a certain air gap, and a rotation shaft 355 rotatably supported at a shaft center of the rotation supporting unit 341 and having a lower end integrally rotatably connected to the rotor 353. Here, the rotor 353 may preferably include a plurality of permanent magnets disposed at an outer side of the stator 351 with a certain air gap from the stator 351, the magnets being spaced apart from each other on the same circumference.

The receiving space 342 is formed in the rotation supporting unit 341. A shaft supporting unit 345 for receiving and rotatably supporting the rotation shaft 355 is formed at a lower portion of the rotation supporting unit 341. Each end portion of the inlet tube 313 and the outlet tube 312 is connected to the shaft supporting unit 345 with being spaced apart from each other in a vertical direction. A separation preventing unit 357 for preventing a separation of the rotation shaft 355 is formed at ah upper end of the rotation shaft 355. Thrust bearings 359 are interposed between the separation preventing unit 357 and the rotation supporting unit 341. Here, the thrust bearings 359 are respectively fixed to the rotation supporting unit 341 and the separation preventing unit 357 to thus control the vertical movement of the rotation shaft 355.

Connection ports 360 which are concaved in a radio direction of the rotation shaft 355 and extended in a circumferential direction thereof are formed at the circumferential surface of the rotation shaft 355. The connection ports 360 are spaced from each other in a vertical direction of the rotation shaft 355. Sealing members 365 each having an O-ring shape are respectively installed at upper and lower portions of each connection port 360 to prevent leakage of brine (or refrigerant). A passage 426 for the second refrigerant in each rotating wing portion 420 of the external air supplying unit 400 which is to be explained later is connected to each of the connection ports 360.

The external air supplying unit 400, on the other hand, includes a hub 410 having a cylindrical shape and rotatably coupled to a circumference of the rotation supporting unit 341, and a plurality of wing portions 420 outwardly extended from the hub 410 in the radial direction of the hub 410 and spaced apart from each other in a circumferential direction of the hub 410.

The hub 410 has a cylindrical shape, and a center portion of a lower surface of the hub 410 is integrally rotatably coupled to a lower end of the rotation shaft 355. The rotor 353 is integrally rotatably formed at the inner surface of the hub 410. Each of the wing portions 420 is extended from the outer surface of the hub 410 in the radial direction of the hub 410, and integrally rotatably coupled to the hub 410. Each of the wing portions 420 is formed such that a leading edge thereof is disposed at an upper side relative to a tailing edge thereof in its rotation direction so as to allow air to flow downwardly when each wing portion 420 rotates.

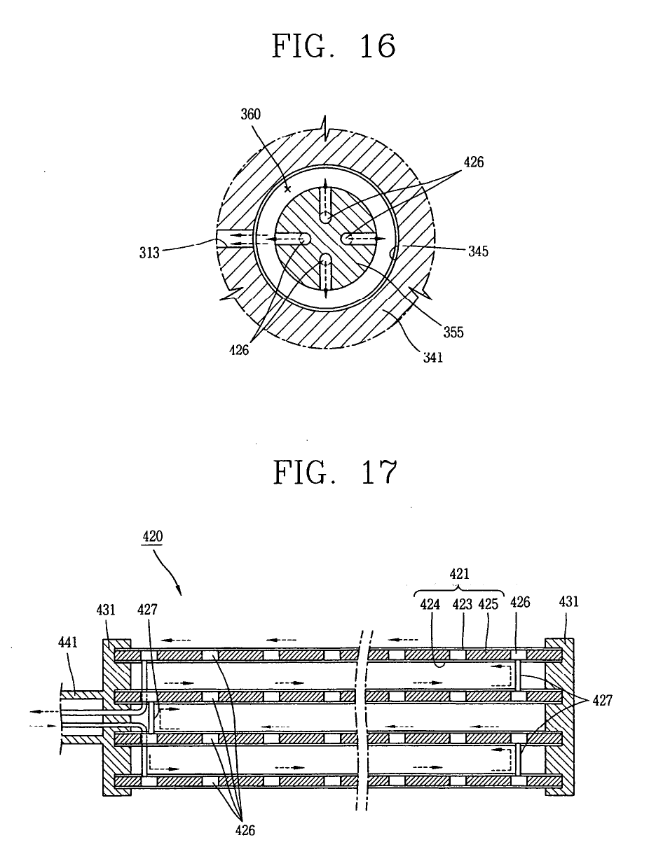

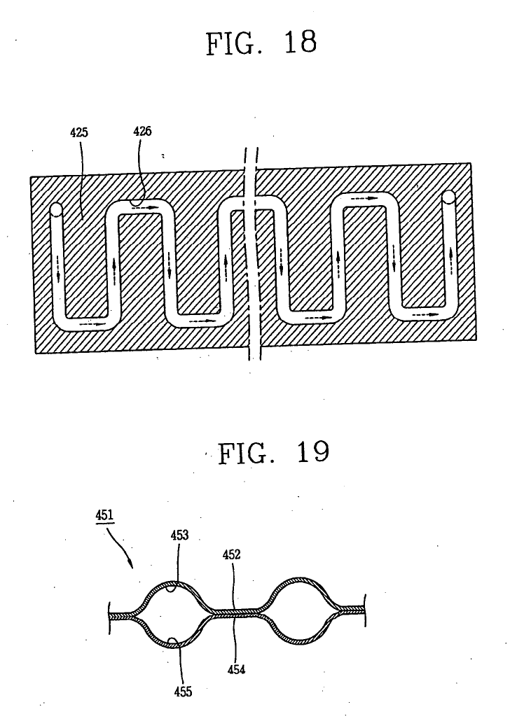

Each wing portion 420, as shown in FIGS. 17 and 18, includes a plurality of heat exchanging portions 421 each formed in a plate shape to have therein passages 426 for the second refrigerant communicated with each other such that the second refrigerant can flow therein and be heat-exchanged, wherein the plurality of heat exchanging portions 421 are disposed to be spaced apart from each other in a thickness direction, supporting portions 431 for supporting each heat exchanging portion 421 with an air gap such that air can flow between each heat exchanging portion 421 and be heat-exchanged, and connection portions 441 for connecting and supporting each of the heat exchanging portion 421 and the supporting portion 431 thus to be rotatable together with the hub 410.

Each of the heat exchanging portion 421 includes an upper plate 423 and a lower plate 424 each formed of a heat conductive member to catalyze heat-exchange with indoor air and disposed to be spaced apart from each other in a vertical direction, and a passage forming member 425 interposed between the upper plate 423 and the lower plate 424 for forming the passage 426 for the second refrigerant by cooperating with the upper plate 423 and the lower plate 424. A connection pipe 427 is connected between the heat exchanging portions 421 which are layered together to thus communicate between the passages 426 of two heat exchanging portions 421 adjacent to each other. Here, the heat exchanging portion 421, as shown in FIG. 19, can be a plate type heat exchanger 451 by forming partial passages 453 and 455 for the second refrigerant each having a semi-cylindrical shape at one surface of each of the upper plate 452 and the lower plate 454 and then by coupling the semi-cylindrical partial passages 453 and 455 in a thickness direction to thusly obtain a cylindrical passage for the second refrigerant.

In such configuration, when a cooling operation is started and power is applied to the driving unit 350, the rotor 353 rotates together with the rotation shaft 355, and accordingly each wing portion 420 rotates centering around the rotation supporting unit 341. By the rotation of each of the wing portions 420 each having the leading edge disposed at an upper side as compared to the tailing edge, air which has been heat-exchanged by contacting with the heat exchanging portions 421 of each wing portion 420 evenly flows downwardly to thereby cool the indoor room.

When starting the cooling operation, the four-way valve 213 switches a passage so as to allow a refrigerant compressed by the compressor 211 to flow toward the first heat exchanger 221. The refrigerant flowing into the first heat exchanger 221 is heat-exchanged with outdoor air to be condensed. The condensed refrigerant is expanded with depressurization through the expansion unit 241, and then flows into the second heat exchanger 231 to be heat-exchanged with the second refrigerant. The refrigerant heat-exchanged with the second refrigerant is sucked into the compressor 211 via the four-way valve and the accumulator 215, and then the sucked refrigerant is compressed and discharged, which operations are repeatedly performed.

The second refrigerant which has been heat-exchanged with the first refrigerant and then cooled inside the intermediate heat exchanger 311 is pumped by the circulation pump 321 to flow along the outlet tube 312. The refrigerant flowing into the connection portion 360 along through the outlet tube 312 flows along the passage of each wing portion 420 and thereafter is heat-exchanged with indoor air in each of the wing portions 420. The heat-exchanged refrigerant flows to the connection port 360 formed at the upper side of the rotation shaft 355 through the passage 426, and then flows through the inlet tube 313 of the intermediate heat exchanger 311 to thereafter flow into the intermediate heat exchanger 311, which operations are repeatedly performed.

When starting the heating operation, on the other hand, the four-way valve 213 switches a passage such that the refrigerant discharged from the compressor 211 flows into the second heat exchanger 231. The first refrigerant flowed into the second heat exchanger 231 is heat-exchanged with the second refrigerant inside the intermediate heat exchanger 311 to be then condensed. The condensed refrigerant is expanded with depressurization through the expansion unit 241, and then absorbs latent heat around the first heat exchanger 221 to be evaporated accordingly. The refrigerant passed through the first heat exchanger 221 is sucked into the compressor 211 via the four-way valve 213 and the accumulator 215 to be then compressed and discharged, which operations are repeatedly performed.

The second refrigerant heat-exchanged with the first refrigerant in the intermediate heat exchanger 311 flows through the outlet tube 312, and then flows into each of the wing portions 420 from one of the connection ports 360. The refrigerant diverged into each wing portion 420 is heat-exchanged with indoor air in each of the wing portions 420 to be then joined together at the other connection portion 360. The joined second refrigerant flows into the intermediate heat exchanger 311 through the inlet tube 313 to be heat-exchanged with the first refrigerant, which operations are repeatedly performed.

Hereinafter, effects of the air conditioner according to the present invention will be described as follows.

In the air conditioner according to the present invention, since heat-exchanged air can be supplied by the external air supplying unit at various positions, the heat-exchanged air can be diffused indoors more quickly.

The present invention can also evenly supply heat-exchanged air indoors quickly by supplying the heat-exchanged air forcibly circulating indoor air by the rotation of the external air supplying unit.

The present invention can quickly diffuse heat-exchanged air indoors by distributing injection holes for injecting the heat-exchanged air at a wider portion and discharging the heat-exchanged air in various directions.

In addition, the present invention can forcibly circulate indoor air without changing temperature of the indoor air only by rotating the external air supplying unit under a state that a refrigerating cycle is not driven.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. An air conditioner comprising:
a casing having a receiving space therein and mounted in a ceiling; and
an air supplying unit installed below the casing for diffusing heat-exchanged air indoors.

2. The air conditioner of claim 1, wherein the air supplying unit is rotatable with respect to the casing.

3. The air conditioner of claim 2, wherein the casing has inlets and outlets, an indoor heat exchanger and a blowing fan are provided inside the casing, and the air supplying unit has an air passage therein.

4. The air conditioner of claim 3, wherein the air supplying unit includes a hub having an air passage therein and rotatably coupled to the casing, and a plurality of rotating wings each having an air passage therein and having one end outwardly extended from the hub.

5. The air conditioner of claim 4, wherein the rotating wings are coupled to the hub such that each inclination is adjustable.

6. The air conditioner of claim 4, wherein the rotating wings are rotated by discharging air to a backward with respect to the rotation direction thereof.

7. The air conditioner of claim 6, wherein the rotating wings include injection holes for injecting air in a length direction thereof.

8. The air conditioner of claim 3, further comprising an outdoor unit having a compressor for compressing a refrigerant and an outdoor heat exchanger to thus create a refrigerating cycle together with the indoor heat exchanger.

9. The air conditioner of claim 3, further comprising a driving unit for rotating the air supplying unit.

10. The air conditioner of claim 9, wherein the driving unit includes a stator fixed to a rotation supporting unit extended from the casing, and a rotor rotated by the stator and connected to the air supplying unit.

11. The air conditioner of claim 9, wherein the air supplying unit includes a hub having an air passage therein, and a plurality of rotating wings each having an air passage therein and outwardly extended from the hub, wherein each of the rotating wings has injection holes for injecting air.

12. The air conditioner of claim 11, wherein an injection hole for injecting air is formed at an end portion in a length direction of each of the rotating wings.

13. An air conditioner comprising:
a first refrigerant circulating unit including a compressor for compressing a first refrigerant, first and second heat exchangers connected to the compressor to allow circulation of the first refrigerant, and an expansion unit disposed between the first and second heat exchangers; and
a second refrigerant circulating unit including a casing having a receiving space therein and mounted in a ceiling; an external air supplying unit movably installed below the casing, having therein a refrigerant passage for flowing a second refrigerant, and in which the second refrigerant is heat-exchangeable with indoor air, an intermediate heat exchanger formed to be heat-exchangeable with the first or second heat exchanger such that the second refrigerant is heat-exchanged with the first refrigerant, and connected to the external air supplying unit, and a circulation pump for circulating the second refrigerant to pass through the external air supplying unit and the intermediate heat exchanger.

14. The air conditioner of claim 13, wherein the external air supplying unit includes a hub rotatable with respect to the case, and a plurality of rotating wings each having one end portion outwardly extended from the hub, wherein the second refrigerant flows and is heat-exchanged in the plurality of rotating wings.

15. The air conditioner of claim 14, wherein each of the rotating wings includes a plurality of heat exchanging units which are layered together and spaced apart from each other in a thickness direction, and connected together such that passages formed therein are communicated with each other.

16. The air conditioner of claim 14, wherein the second refrigerant circulating unit further includes a rotation supporting unit for rotatably supporting the external air supplying unit and a driving unit for rotating the external air supplying unit.

17. The air conditioner of claim 16, wherein the hub is rotatably coupled to a circumference of the rotation supporting unit, and the driving unit includes a rotation shaft rotatably coupled to a shaft center of the rotation supporting unit and having one end integrally coupled to the hub, a stator formed to surround the rotation supporting unit, and a rotor rotatably disposed to be spaced apart from the stator with a certain air gap in the hub.

18. The air conditioner of claim 17, wherein connection ports are formed at a circumference of the rotation shaft to be concaved in a radial direction of the circumference and extended in the circumferential direction, and each rotating wing is connected to any of the connection ports such that a passage formed in each rotating wing is communicated to the corresponding connection port.

19. The air conditioner of claim 14, wherein each of the rotating wings is rotatably coupled to the hub.

20. The air conditioner of claim 13, wherein the first refrigerant circulating unit further includes a four-way valve disposed at a discharge side of the compressor for switching a passage.

21. An air conditioner comprising:
a casing having a receiving space therein and mounted in a ceiling;
an external air supplying unit having a refrigerant passage for flowing a refrigerant therein and rotatably installed below the casing;
a heat exchanger installed inside the casing, connected to the external air supplying unit to allow the flow of the refrigerant, and adapted to heat or cool the refrigerant by means of a heating member or cooling member; and
an indoor unit having a driving unit for rotating the external air supplying unit.
